(19) United States
(12) Patent Application Publication
(10) Pub. No.: US 2024/0097409 A1
(43) Pub. Date: Mar. 21, 2024

(54) ENERGY MANAGEMENT MODULE

(71) Applicant: Savant Systems, Inc., Hyannis, MA (US)

(72) Inventors: Siegmar K. Eschholz, Southwest Harbor, ME (US); Peter H. Corsini, East Sandwich, MA (US); Richard C. Hedderich, Lehi, UT (US); Jon R. Magnussen, Barrington, RI (US)

(21) Appl. No.: 17/886,900

(22) Filed: Aug. 12, 2022

(51) Int. Cl. H02B 1/04; G01R 21/06; H02B 1/20; H02B 3/00

(52) U.S. Cl. CPC H02B 1/04; G01R 21/06; H02B 1/20; H02B 3/00

(57) ABSTRACT

In one embodiment, an energy management module having a form factor adapted to fit within one or more slots of a load center or panelboard of a structure is provided. The energy management module includes a housing configured to fit within the one or more slots of the load center or panelboard. It has a plurality of current sensor connectors configured to connect to current sensors that measure current flowing through breakers of the load center or panelboard to circuits within the structure. One or more power measurement DSPs are provided to measure power consumption of the circuits. It further has a microcontroller unit with a wireless network interface configured to communicate the power consumption measurements to a host controller or cloud services that provide the power consumption measurements for display in an energy management user interface.

### BACKGROUND

### Technical Field

The present disclosure relates generally to energy management and more specifically to devices configured to measure and/or control power consumption of circuits within a structure (e.g., a residential or commercial building).

### Background Information

With the rising cost of electrical power and greater awareness of environmental impacts, there has been increased interest in monitoring and controlling power supplied to circuits within structures. This includes power flowing through a main breaker of a load center or panelboard (often simply called a “breaker box”) of the structure, as well as power flowing through individual circuit breakers that supply specific loads (e.g., light fixtures, wall outlets, appliances, HVAC equipment, etc.). A variety of energy management systems have been developed to address these tasks. However, existing energy management systems typically require accessory components that must be installed nearby, but external to, the load center or panelboard, in order to perform monitoring or control functions. The requirement for such external accessory components complicates installations, consumes additional space in utility rooms, and increases costs. There is a need for improved solutions that do not require accessory components nearby, but external, to the load center or panelboard.

### SUMMARY

In one embodiment, an energy management module (e.g., standalone energy management (SEM) module) having a form factor adapted to fit within one or more slots of a load center or panelboard is provided. The form factor may be that of a two-pole breaker that fits within two slots of the load center or panelboard, being retained therein by a combination of one or more tabs that engage a retainer bar and one more clips that engage and are electrically connected to a hot bus bar. The SEM module may include a plurality of current sensor connectors configured to connect to current sensors (e.g., split-core, clip-on Hall Effect current sensors) that measure current flowing through breakers (e.g., a main breaker and individual circuit breakers) to circuits. One or more power measurement digital signal processors (DSPs) may be configured to measure power consumption of the circuits, using the measured currents and voltage on the hot bus bars. The SEM module may include a microcontroller unit having a wireless network interface (e.g., a Wi-Fi interface, Bluetooth low energy (BLE) interface, etc.) configured to communicate the power consumption measurements to a host controller or cloud services of an energy management system. The host controller or cloud services may provide the power consumption measurements in an energy management user interface of a control application (app) that may executed on a mobile device. The SEM module may also include a local user interface configured to locally display at least some of the power consumption measurements.

In some implementations, the SEM module may include an integrated panel bridge controller (PBC) that is configured to communicate via a wireless network interface (e.g., BLE interface) with one or more companion modules internal to the load center or panelboard associated with respective breakers. The PBC may receive data from the companion modules and forward it to the host controller or cloud services, and send control commands to the companion modules on behalf of the host controller or cloud services to perform energy management functions.

It should be understood that a variety of additional features and alternative embodiments may be implemented. This Summary is intended simply as a brief introduction to the reader, and does not indicate or imply that the examples mentioned herein cover all aspects of the invention, or are necessary or essential aspects of the invention.

### BRIEF DESCRIPTION OF THE DRAWINGS

The description below refers to the accompanying drawings, of which:

FIG. 1 is a block diagram of an example architecture of an energy management system that may include an SEM module;

FIG. 2 is an enlarged diagram of an example load center or panelboard showing interconnections between a SEM module and other components within the load center or panelboard;

FIG. 3 is a block diagram of internal components of a first example SEM module that lacks an integrated PBC;

FIG. 4 is a block diagram of internal components of a second example SEM module that includes an integrated PBC; and

FIG. 5 is an example configuration screen that may be presented by a control app on a mobile device to configure a SEM module.

### DETAILED DESCRIPTION

### Definitions

As used herein, the term “home automation system” refers to a system that controls at least one of audio/video, lighting, heating ventilation and air conditioning (HVAC) or energy functionality in a structure (e.g., a residential or commercial building).

As used herein, the term “energy management system” refers to a system for monitoring and/or controlling energy consumption, generation and/or storage within a structure (e.g., a residential or commercial building). An energy management system may be a component of a home automation system, or a standalone system.

As used herein, the term “mobile device” refers to an electronic device that executes a general-purpose operating system and is adapted to be transported on one's person. Devices such as smartphones should be considered mobile devices. Desktop computers, servers, or other primarily-stationary computing devices generally should not be considered mobile devices.

As used herein, the term “companion module” refers to a device having a form factor adapted to fit within one or more slots of a load center or panelboard and that is configured to monitor and control a circuit of an associated circuit breaker of the load center or panelboard.

As used herein, the term “panel bridge controller” or PBC refers to a device that is configured to communicate with one or more companion modules associated with respective breakers within a load center or panelboard to receive data from and send control commands to the one or more companion modules as part of an energy management system. A PBC may be a standalone device or integrated into a multi-function device.

### EXAMPLE EMBODIMENTS

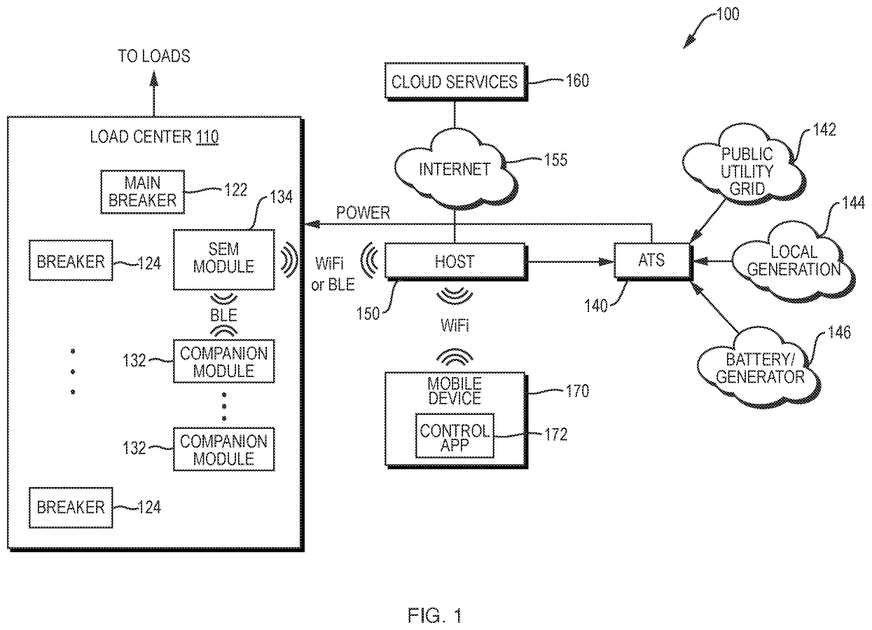

FIG. 1 is a block diagram of an example architecture 100 of an energy management system that may include an SEM module. A load center or panelboard (often simply called a “breaker box”) 110 may be provided with power via an automatic transfer switch (ATS) 140 originating from a public utility grid 142, local generation (e.g., solar, wind, etc.) 144 and/or a local battery or generator 146. The ATS 140 may be an intelligent power switching device having a microprocessor-based controller configured to automatically switch and load balance between the power sources.

The load center or panelboard 110 may include a main breaker 122 through which all power flows and a number of individual circuit breakers 124 that each distribute power to one or more circuits that supply loads (e.g., light fixtures, wall outlets, appliances, HVAC equipment, etc.) within the structure. In some cases, circuit breakers 124 may be associated with (e.g., wired in series with) respective companion modules 132 that monitor and control their circuits. Each companion module 132 may include on or more relays configured to control (i.e. turn on or off) respective circuits, one or more current sensors (e.g., Hall Effect current sensors) configured to measure current flowing to such circuits, a power measurement DSP configured to measure power consumption (e.g., instantaneous power consumption, average power consumption, peak power consumption, etc.) of loads coupled to the circuits, a microcontroller with an integrated wireless network interface (e.g., a BLE interface) configured send data and receive and implement control commands, and a local user interface (e.g., a LCD screen and switches/buttons) configured to locally display data and/or receive local control commands. Where circuit breakers have associated companion modules 132, current and voltage may be measured by the companion module. However, in some implementations, there may not be associated companion modules 132 for some circuit breakers or there may be no companion modules at all. Further, in some implementations, there may not be a convenient nearby component (e.g., a dedicated PBC) to receive the data and send the control commands to the companion modules 132.

In part to address these issues, one or more SEM modules 134 may be included in the load center or panelboard 110 that are configured to measure power consumption of loads on the circuits of individual circuit breakers 124 as well as total power consumption through the main breaker 122. Each SEM module 134 may include a microcontroller and wireless network interface to communicate the power consumption measurements to a host controller 150 or cloud services 160 (e.g., using Wi-Fi, BLE, etc.). In some implementations, the SEM module 134 may further include an integrated PBC that is configured to receive data from and send control commands to companion modules 132 via the wireless network interface (e.g., using BLE) on behalf of the host controller 150 or cloud services 160. As discussed further below, the SEM module 134 may have a form factor adapted to fit within one or more slots of the load center or panelboard 110 (e.g., having the form factor of a two-pole breaker).

The host controller 150 may execute host software configured to monitor and control the operations of components of a home automation system of the structure, of which the energy management system such may be a constituent part. The host software when executed may provide a variety of functions including UI interpretation, system administration and monitoring, synchronization with cloud services 160 over the internet 155, activity recording, activity prediction, and/or other types of functions. The host software may maintain a home database that stores configuration information about components of a home automation system, including components of the energy management system such as companion modules 132 and SEM modules 134. At least some of the data in the home database may also be maintained (e.g., redundantly) by the cloud services 160. The host controller 150 may communicate (e.g., via Wi-Fi) with one or more mobile devices 170 that are configured to execute a control app 172. The control app 172 may be configured to present a user interface for monitoring and controlling operations home automation functions, at least a portion of which may be an energy management user interface for monitoring and controlling energy related functions.

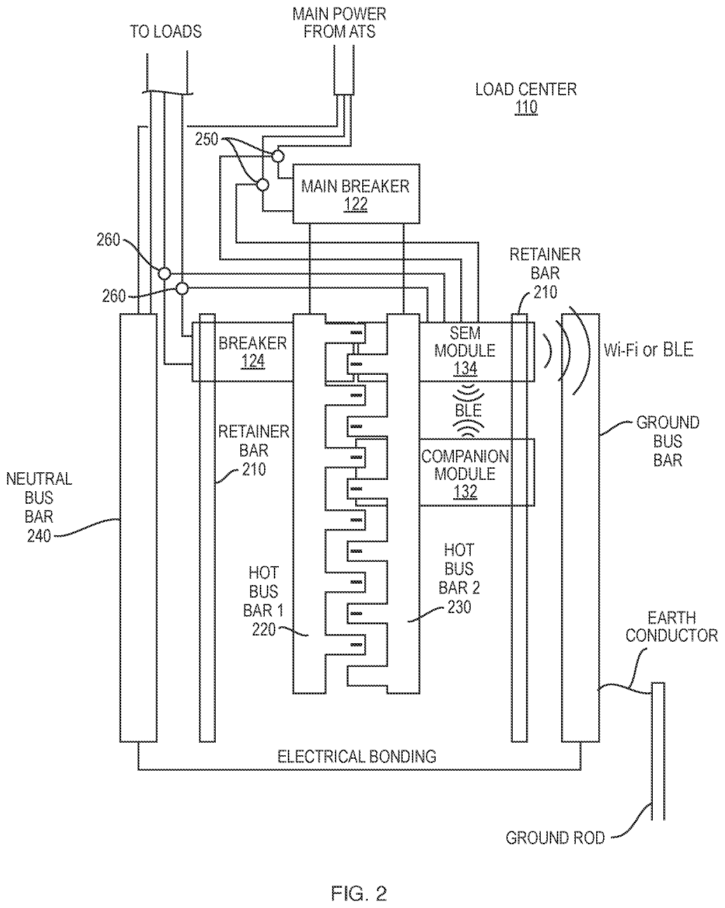

FIG. 2 is an enlarged diagram of an example load center or panelboard 110 showing interconnections between a SEM module 134 and other components within the or panelboard load center. In one embodiment, the load center or panelboard 110 is single-phase 240 volt (V) electrical panel with a current rating up to 200 amperes (A). However, it should be understood that the load center or panelboard 110 may alternatively have different specifications (e.g., be three-phase with differing voltage and current ratings). Similar to FIG. 1, the load center or panelboard 110 may include a main breaker 122 and number of individual circuit breakers 124 associated with companion modules 132. In this example, a single SEM module 134 is installed. However, it should be understood that in other implementations multiple SEM modules 134 may be installed in the load center or panelboard.

The SEM module 134 may have a housing (e.g., a plastic housing) similar to circuit breaker (e.g., a two-pole breaker) sized to fit within one or more slots (e.g., two slots) of the load center or panelboard 110. The SEM module 134 may be retained within the slots by a combination of engagement of one or more tabs molded into the housing with projections of a retainer bar 210 of the load center or panelboard and engagement of one or more metallic clips that protrude through the housing with hot bus bars 220, 230 of the load center or panelboard 110. In addition to providing a retainment function, the one or more metallic clips may also provide an electrical connection to the hot bus bars 220, 230. A terminal protruding through the housing may provide an electrical connection (e.g., via a wire) to a neutral bus bar 240 of the load center or panelboard. Through such electrical connections, the SEM module 134 may derive power to support its operation. Further, the SEM module 134 may also measure voltage on the hot bus bars 220, 230 of the load center or panelboard 110 for use in measuring power.

The SEM module 134 may include a number of (e.g., 12) current sensor connectors (e.g., on pluggable terminal blocks) that extend through the housing and are configured to connect via wires to current sensors (e.g., split-core, clip-on Hall Effect current sensors) 250, 260 associated with (e.g., clipped around) wires within the load center or panelboard 110. Each current sensor may have a respective current rating (e.g., 20 A, 50 A, 150 A, 250 A, 400 A, 600 A etc.) indicating the maximum amount of current it can measure. The current sensors may include current sensors 250 on the positive wires leading to the main breaker 122 to measure current flowing through the main breaker to all circuits as well as current sensors 260 on the positive wires from individual circuit breakers to measure current flowing to individual circuits that supply loads within the structure. Depending on the implementation, current sensors 250, 260 may be provided for all circuits, or for selected circuits.

It should be remembered that in addition to its physical interconnections, the SEM module 132 may further have wireless connections via its wireless network interface to a host controller 150 (e.g., via Wi-Fi, BLE, etc.), and in implementations where it includes an integrated PBC, to companion modules 132 (e.g., via BLE). In implementations where the SEM module 134 includes an integrated PBC, in addition to current measurements via the current sensors 250, 260 additional current measurements may be obtained from the companion modules 132 utilizing their internal current sensors (e.g., Hall Effect current sensors).

The SEM module 134 may further include a LCD screen and switches/buttons (e.g., two switches and a button) that extend through a front face of the housing which provides a local user interface on the module. The local user interface may be used to display at least some power consumption measurements as well as to receive local control commands (e.g., to change the type of display or make selections therein).

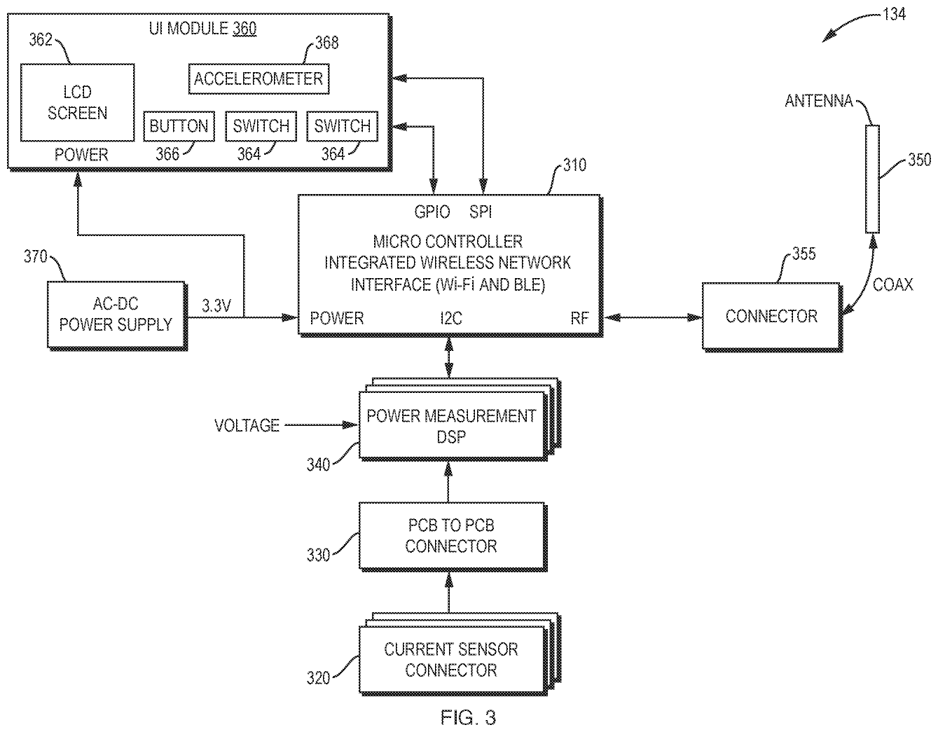

FIG. 3 is a block diagram of internal components of a first example SEM module 134 that lacks an integrated PBC. At the heart of the module 134 is a microcontroller unit 310 having am integrated wireless network interface (e.g., a Wi-Fi/BLE network interface). A plurality of current sensor connectors 320 (e.g., on four 8-position pluggable terminal blocks) are configured to connect to a set of current sensors (e.g., 12 split-core, clip-on Hall Effect current sensors) that measure current flowing through breakers of the load center or panelboard 110 to circuits within the structure. The current sensor connectors 320 are coupled via a PCB to PCB connector 330 to one or more power measurement DSPs (e.g., six 2-channel DSPs) configured to measure power consumption (e.g., instantaneous power consumption, average power consumption, peak power consumption, etc.) of loads coupled to the circuits using the current measurements and voltage on one or more hot bus bars 220, 230 of the load center or panelboard, and provide such measurements to the microcontroller unit 310. The microcontroller unit 310 is configured to communicate the power consumption measurements, using its integrated wireless network interface via an antenna 350 coupled thereto by a connector (e.g., a subminiature version A (SMA) connector) to a host controller 150 or cloud services 160 that provide the power consumption measurements for display in an energy management user interface.

A UI module 360 is also coupled to the microcontroller unit 310 and provides a local user interface for displaying at least some of the power consumption measurements and/or receiving local control commands. The UI module 360 may include a LCD screen 362 and switches/buttons 364, 366. The UI module 360 may also include an accelerometer 368 configured to determine an orientation of the SEM module 134. Depending on the orientation, screens shown on the LCD screen 362 may be rotated so the text and/or graphics thereon are orientated in an upright manner. Power may be provided to components of the SEM module 134, including the microcontroller unit 310 and the UI module 360, from an AC-DC power supply 370 that converts power derived from a hot bus bar 220, 230 of the load center or panelboard 110.

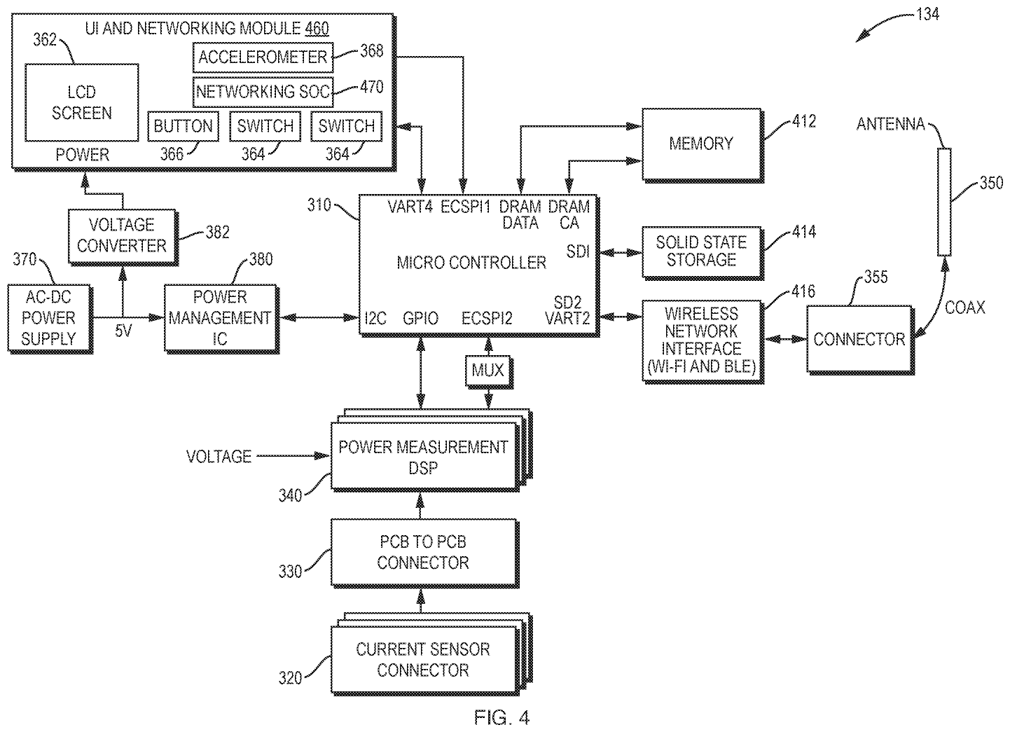

FIG. 4 is a block diagram of internal components of a second example SEM module 134 that includes an integrated PBC. At the heart of the module is a microcontroller unit 410 that is coupled to a memory (dynamic random access memory (DRAM)) 412 and solid state storage (embedded multi-media card (eMMC)) 414 that store an operating system (e.g., a Linux operating system) and application code for PBC functionality. A plurality of current sensor connectors 320 (e.g., (e.g., on four 8-position pluggable terminal blocks) are configured to connect to a set of current sensors (e.g., 12 split-core, clip-on Hall Effect current sensors) that measure current flowing through breakers of the load center or panelboard 110 to circuits within the structure. The current sensor connectors 320 are coupled via a PCB to PCB connector 330 to one or more power measurement DSPs (e.g., six 2-channel DSPs) configured to measure power consumption (e.g., instantaneous power consumption, average power consumption, peak power consumption, etc.) of loads coupled to the circuits, using the current measurements and voltage on one or more hot bus bars 220, 230 of the load center or panelboard, and provide such measurements to the microcontroller unit 410. The microcontroller unit 410 is configured to communicate the power consumption measurements, using a wireless network interface (e.g., a Wi-Fi/BLE network interface) coupled to an antenna 350 by a connector (e.g., SMA connector), to a host controller 150 or cloud services 160 that provide the power consumption measurements for display in an energy management user interface. The microcontroller unit 410 is further configured to implement PCB functionality under the direction of the host controller 150 or cloud services 160.

A UI and networking module 460 is also coupled to the microcontroller unit 310 and provides a local user interface for displaying at least some of the power consumption measurements and/or receiving local control commands as well as a further wireless network interface (e.g., a BLE network interface) for receiving data from and send control commands to companion modules 132. The UI and networking module 460 may include a LCD screen 362 and switches/buttons 364, 366. The UI and networking module 460 may also include an accelerometer 368 configured to determine an orientation of the SEM module 134. Depending on the orientation, screens shown on the LCD may be rotated so the text and/or graphics thereon are orientated in an upright manner. Further, the UI and networking module 460 may include a networking system-on-a-chip (SOC) (e.g., a Bluetooth SOC) adapted to communicate with companion modules 132 as part of PBC functions. Power may be provided to components of the SEM module 134, including the microcontroller unit 310 and the UI and networking module 460, from a AC-DC power supply 370 that converts power derived from a hot bus bar 220, 230 of the load center or panelboard 110. A power management integrated circuit (IC) 380 and a voltage convert 382 may be used to regulate and convert such power.

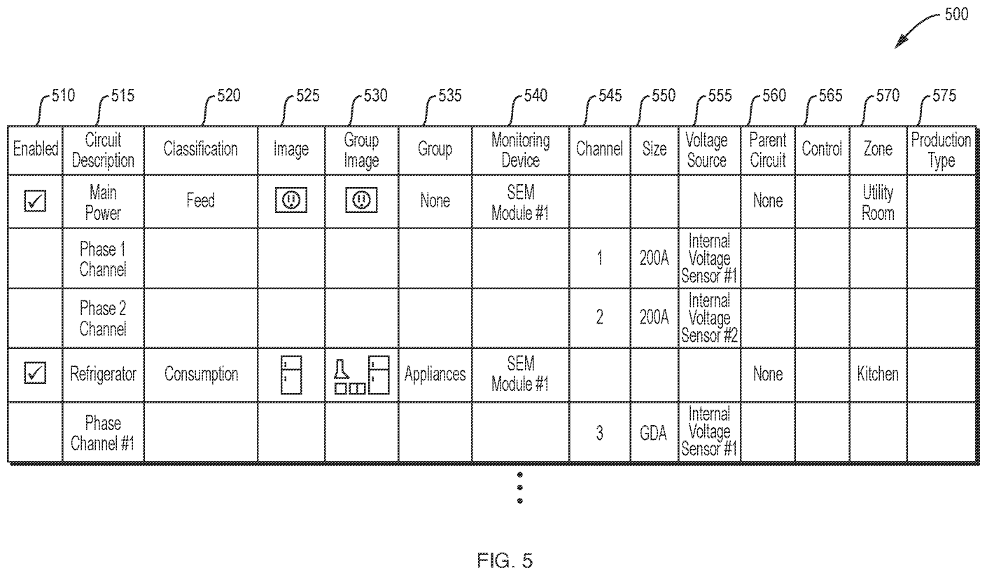

FIG. 5 is an example configuration screen 500 that may be presented by a control app 172 on a mobile device 170 to configure a SEM module 134. At least some of the configuration may be stored in the home database. For each circuit the user may select/or deselect an enable field 510 to indicate if the circuit is to appear within an energy management user interface provided by the control app 172. The user may enter a category describing the physical wiring to which current sensors 250, 260 are attached in a circuit description field 515 and a classification (e.g., consumption, production, feed) in a classification field 520. Using an image field 525, a group image field 530, and a group name field 535, the user may customize the appearance of power consumption information in the energy management user interface. The user may enter an identification of the SEM module 134 in a monitoring device field 540 and an identification of the current sensor connector 320 the circuit is being monitored by in a channel field 545. A size of the circuit may be entered in a size field 550 and an identification of the source of voltage measurements for power calculations in a voltage source field 555. A user may enter further information describing the organization and properties of the monitored circuit and its relation to a greater home automation system in a parent circuit field 560, control field 565, home automation zone field 570 and production type field 575.

It should be understood that various adaptations and modifications may be made to the above discussed SEM module 134. It should be understood that at least some of the functionality suggested above to be implemented in hardware may be implemented in software, and vice versa. In general functionality may be implemented in hardware, software or various combinations thereof. Hardware implementations may include logic circuits, application specific integrated circuits, and/or other types of hardware components. Software implementations may include electronic device-executable instructions (e.g., computer-executable instructions) stored in a non-transitory electronic device-readable medium (e.g., a non-transitory computer-readable medium), such as a volatile or persistent memory, a hard-disk, a compact disk (CD), or other tangible medium. Further, combined software/hardware implementations may include both electronic device-executable instructions stored in a non-transitory electronic device-readable medium, as well as one or more hardware components, for example, processors, memories, etc. Above all, it should be understood that the above embodiments are meant to be taken only by way of example.

What is claimed is:

1. An energy management module having a form factor adapted to fit within one or more slots of a load center or panelboard of a structure, comprising:
a housing configured to fit within the one or more slots of the load center or panelboard;
a plurality of current sensor connectors configured to connect to current sensors that measure current flowing through breakers of the load center or panelboard to circuits within the structure;
one or more power measurement digital signal processors (DSPs) configured to measure power consumption of the circuits; and
a microcontroller unit having a wireless network interface configured to communicate the power consumption measurements to a host controller or cloud services that provide the power consumption measurements for display in an energy management user interface.

2. The energy management module of claim 1, further comprising:
one or more clips each configured to engage and be electrically connected to a hot bus bar of the load center or panelboard; and
a terminal electrically connected to a neutral bus bar of the load center or panelboard.

3. The energy management module of claim 2, wherein the one or more power measurement DSPs are configured to measure power consumption of the circuits using a voltage supplied over the one or more clips.

4. The energy management module of claim 2, wherein the housing further comprises one or more tabs each configured to engage a retainer bar of the load center or panelboard, wherein a combination of the one or more tabs and the one or more clips retain the energy management module within the one or more slots of the load center or panelboard.

5. The energy management module of claim 1, wherein the one or more slots are two slots and the form factor is of a two-pole breaker.

6. The energy management module of claim 1, wherein the wireless network interface comprises a Wi-Fi or Bluetooth low energy (BLE) interface configured to communicate the power consumption measurements to the host controller or the cloud services.

7. The energy management module of claim 1, further comprising:
a local user interface configured to locally display at least some of the power consumption measurements and/or receive local control commands.

8. The energy management module of claim 1, wherein the breakers include a main breaker of the load center or panelboard and a plurality of individual circuit breakers such that the current sensors measure current flowing through the main breaker and current flowing through the plurality of individual circuit breakers to circuits that supply loads.

9. The energy management module of claim 1, further comprising:
an integrated panel bridge controller (PBC) that is configured to communicate via the wireless network with one or more companion modules associated with respective breakers within the load center or panelboard, and to receive data from and send control commands to the one or more companion modules.

10. The energy management module of claim 9, wherein the wireless network interface comprises a Bluetooth low energy (BLE) interface configured to receive data from and send control commands to the one or more companion modules.

11. An energy management module having a form factor adapted to fit within one or more slots of a load center or panelboard of a structure, comprising:
one or more clips each configured to engage and be electrically connected to a hot bus bar of the load center or panelboard;
a terminal electrically connected to a neutral bus bar of the load center or panelboard;
a plurality of current sensor connectors configured to connect to current sensors that measure current flowing through breakers of the load center or panelboard to circuits within the structure;
one or more power measurement digital signal processors (DSPs) configured to measure power consumption of the circuits; and
a microcontroller unit configured to communicate the power consumption measurements to a host controller or cloud services.

12. The energy management module of claim 11, wherein the one or more power measurement DSPs are configured to measure power consumption of the circuits using a voltage supplied over the one or more clips.

13. The energy management module of claim 11, wherein the wireless network interface comprises a Wi-Fi or Bluetooth low energy (BLE) interface configured to communicate the power consumption measurements to the host controller or the cloud services.

14. The energy management module of claim 11, further comprising:
a local user interface configured to locally display at least some of the power consumption measurements and/or receive local control commands to control the local display.

15. The energy management module of claim 11, wherein the breakers include a main breaker of the load center or panelboard and a plurality of individual circuit breakers such that the current sensors measure current flowing through the main breaker and current flowing through the plurality of individual circuit breakers to circuits that supply loads.

16. The energy management module of claim 11, further comprising:
an integrated panel bridge controller (PBC) that is configured to communicate via the wireless network with one or more companion modules associated with respective breakers within the load center or panelboard, and to receive data from and send control commands to the one or more companion modules.

17. The energy management module of claim 16, wherein the wireless network interface comprises a Bluetooth low energy (BLE) interface configured to receive data from and send control commands to the one or more companion modules.

18. A method for using an energy management module having a form factor adapted to fit within one or more slots of a load center or panelboard of a structure, comprising:
installing the energy management module within the one or more slots of the load center or panelboard;
connecting a plurality of current sensor connectors of the energy management module to a plurality of current sensors that measure current flowing through breakers of the load center or panelboard to circuits within the structure;
configuring the energy management module with information describing the circuits within the structure; and
configuring the energy management module to communicate to a host controller or cloud services power consumption measurements for the circuits within the structure based on the measured current flows.

19. The method of claim 18, wherein the installing the energy management module further comprises:
engaging one or more clips of the energy management module to a hot bus bar of the load center or panelboard; and
connecting a terminal of the energy management module to a neutral bus bar of the load center or panelboard.

20. The method of claim 18, further comprising:
configuring the energy management module to operate as an integrated panel bridge controller (PBC) of the load center or panelboard such that it communicates with one or more companion modules associated with respective breakers within the load center or panelboard to receive data from and send control commands to the one or more companion modules.
